(19) United States
(12) Patent Application Publication
(10) Pub. No.: US 2013/0298976 A1
(43) Pub. Date: Nov. 14, 2013

(54) SOLAR CELL AND MANUFACTURING METHOD THEREOF

(71) Applicant: SAMSUNG ELECTRONICS CO., LTD., Suwon-si (KR)

(72) Inventors: Ji-Eun CHANG, Yongin-si (KR); Myoung-Gyun SUH, Seoul (KR); Jin-Seong HEO, Seoul (KR)

(73) Assignee: SAMSUNG ELECTRONICS CO., LTD., Suwon-Si (KR)

(21) Appl. No.: 13/649,483

(22) Filed: Oct. 11, 2012

(30) Foreign Application Priority Data
May 8, 2012 (KR) 10-2012-0048619

(51) Int. Cl. H01L 31/06; H01L 31/0224

(52) U.S. Cl. 136/255; 136/256

(57) ABSTRACT

According to example embodiments, a solar cell includes a photovoltaic layer, a plurality of front electrodes, a rear electrode, and a transparent subsidiary electrode. The plurality of front electrodes and the rear electrode are disposed respectively on front and rear surfaces of the photovoltaic layer. The subsidiary electrode is disposed on front surfaces of the photovoltaic layer and the front electrodes. The subsidiary electrode may be graphene.

### RELATED APPLICATIONS

This application claims priority under 35 U.S.C. §119 to Korean Patent Application No. 10-2012-0048619 filed in the Korean Intellectual Property Office on May 8, 2012, the entire contents of which are incorporated herein by reference.

### BACKGROUND

(a) Field

Example embodiments relate to a solar cell and/or a manufacturing method thereof.

(b) Description of the Related Art

Fossil fuels, such as coal and petroleum, are used as energy sources. However, fossil fuels are being exhausted and cause global warming and environmental pollution. Solar light, tidal power, wind power, geothermal heat and the like are being studied as alternative energy sources for replacing fossil fuels.

Among them, technology of converting solar light into electricity takes the lead. Various materials and devices are being developed for solar cells that convert solar light into electricity. Solar cells may have a multi-layered p-n junction structure and may include group III-V materials.

A solar cell may include a photovoltaic layer and electrodes connected thereto. The electrodes may be disposed on a front surface and/or a rear surface of the photovoltaic layer. A front electrode on the front surface of the photovoltaic layer may have a smaller area or a smaller width than that of a solar cell in order to block less incident light, which may increase resistance and may reduce efficiency of power generation due to the high current density. In particular, the efficiency of a concentrator solar cell where high concentration of photons are incident in a small area to generate high concentration of electron-hole pairs may be decreased due to an increased recombination ratio caused by series resistance under the light-concentrated condition.

### SUMMARY

According to example embodiments, a solar cell includes: a rear electrode; a photovoltaic layer on the rear electrode; a plurality of front electrodes on a front surface of the photovoltaic layer; and a transparent subsidiary electrode on the front surface of the photovoltaic layer and a front surface of the plurality of front electrodes.

The subsidiary electrode may include graphene.

The solar cell may further include a concentrating member configured to concentrate incident light and to provide the concentrated light to the photovoltaic layer.

The concentrating member may have a concentration ratio equal to or greater than about 180.

The photovoltaic layer may include a first semiconductor film and a second semiconductor film that form a first junction and have different conductivity types.

The photovoltaic layer may further include a window film between the first semiconductor film and at least one of the plurality of front electrodes. The window film and the first semiconductor film may form a second junction.

The photovoltaic layer may further include a back surface field film between the second semiconductor film and the rear electrode. The back surface field film and the second semiconductor film may form a third junction.

The solar cell may further include a contact layer between the window film and at least one of the plurality of front electrodes. The contact layer may be configured to reduce electrical resistance between the window film and at least one of the plurality of front electrodes.

The solar cell may further include an anti-reflection coating on a front surface of the subsidiary electrode.

According to example embodiments, a solar cell includes: a rear electrode; a plurality of photovoltaic layers on the rear electrode; at least one intermediate layer between adjacent photovoltaic layers among the plurality of photovoltaic layers; a plurality of front electrodes on a front surface of the plurality of the photovoltaic layers; and a transparent subsidiary electrode on a front surface of the plurality of the photovoltaic layers and a front surface of the plurality of front electrodes.

The subsidiary electrode may include graphene.

The solar cell may further include a concentrating member configured to concentrate incident light and to provide the concentrated light to the plurality of the photovoltaic layers.

The concentrating member may have a concentration ratio equal to or greater than about 180.

At least one of the plurality of the photovoltaic layers may include a first semiconductor film and a second semiconductor film that form a first junction and have different conductivity types.

The at least one of the plurality of the photovoltaic layers may further include a window film between the first semiconductor film and at least one of the plurality of front electrodes. The window film and the first semiconductor film may form a second junction.

The at least one of the plurality of the photovoltaic layers may further include a back surface field film between the second semiconductor film and the rear electrode. The back surface field film and the second semiconductor film may form a third junction.

The solar cell may further include a contact layer between the window film and the at least one of the plurality of front electrodes, wherein the contact layer is configured to reduce electrical resistance between the window film and the at least one of the plurality of front electrodes.

The at least one intermediate layer may have a P-N junction structure.

The solar cell may further include an anti-reflection coating on a front surface of the subsidiary electrode.

According to example embodiments, a method of manufacturing a solar cell includes: forming a graphene layer on a catalyst layer; attaching a transfer substrate on the graphene layer; forming a subsidiary electrode on a plurality of electrodes and a photovoltaic layer of a laminate by adhering the graphene layer with the transfer substrate to the laminate; and removing the transfer substrate from the subsidiary electrode. The laminate may include the photovoltaic layer and the plurality of front electrode on a rear electrode.

According to example embodiments a solar cell includes: a laminating including a plurality of front electrodes and a photovoltaic layer on a rear electrode; and a subsidiary electrode on the plurality of front electrodes and the photovoltaic layer of the laminate. The subsidiary electrode may be formed by a process that includes: forming a graphene layer on a catalyst layer, attaching a transfer substrate on the graphene layer, adhering the graphene layer to the plurality of front electrodes and the photovoltaic layer of the laminate, and removing the substrate.

### BRIEF DESCRIPTION OF THE DRAWINGS

The foregoing and other features and advantages of example embodiments will be apparent from the more particular description of non-limiting embodiments, as illustrated in the accompanying drawings in which like reference characters refer to the same parts throughout the different views. The drawings are not necessarily to scale, emphasis instead being placed upon illustrating the principles of inventive concepts. In the drawings:

FIG. 1 is a schematic sectional view of a solar cell according to example embodiments.

FIG. 2 is a schematic plan view of an example front electrode in the solar cell shown in FIG. 1.

FIG. 3 to FIG. 5 are schematic sectional views illustrating a method of manufacturing a subsidiary electrode in the solar cell shown in FIG. 1.

FIG. 6 to FIG. 13 are schematic sectional views of solar cells according to example embodiments.

FIG. 14 is a schematic sectional view of a solar cell according to experiments.

FIG. 15, FIG. 16, and FIG. 18 to FIG. 21 are schematic sectional views illustrating a method of forming a subsidiary electrode of a solar cell according to experiments.

FIG. 17 is a graph showing a process condition for forming a subsidiary electrode of a solar cell according to experiments.

FIG. 22 is a graph showing a short-circuit current of a solar cell according to an experiment and a comparative example as function of the concentration ratio.

FIG. 23 is a graph showing an open-circuit voltage of a solar cell according to an experiment and a comparative example as function of the concentration ratio.

FIG. 24 is a graph showing a fill factor of a solar cell according to an experiment and a comparative example as function of the concentration ratio.

FIG. 25 is a graph showing an efficiency of a solar cell according to an experiment and a comparative example as function of the concentration ratio.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted. In the drawing, parts having no relationship with the explanation are omitted for clarity.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

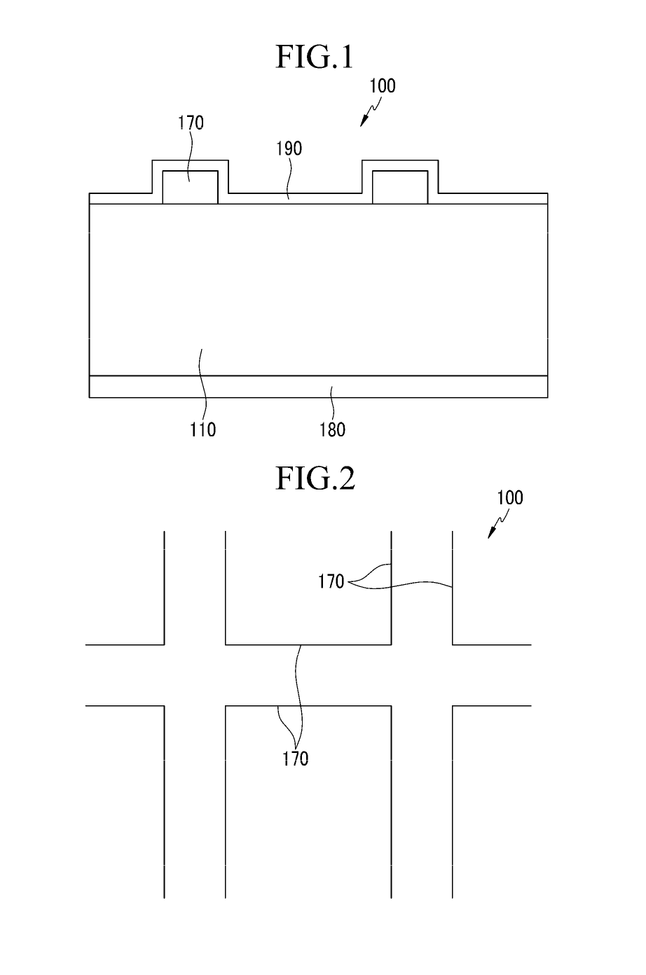

A solar cell according to example embodiments is described in detail with reference to FIG. 1 to FIG. 5.

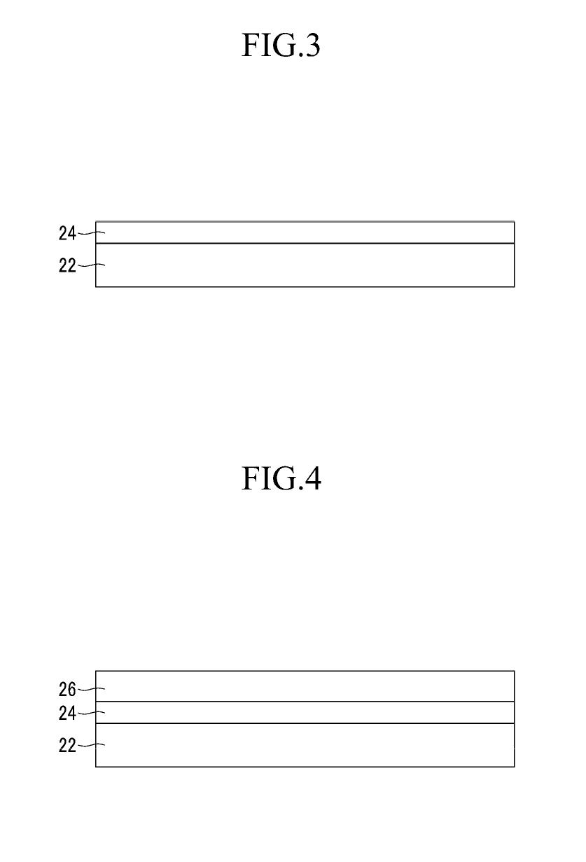

FIG. 1 is a schematic sectional view of a solar cell according to example embodiments. FIG. 2 is a schematic plan view of an example front electrode in the solar cell shown in FIG. 1. FIG. 3 to FIG. 5 are schematic sectional views illustrating a method of manufacturing a subsidiary electrode of the solar cell shown in FIG. 1.

Referring to FIG. 1, a solar cell 100 according to example embodiments may include a photovoltaic layer 110, a plurality of front electrodes 170 disposed on a front surface of the photovoltaic layer 110, a rear electrode 180 disposed on a rear surface of the photovoltaic layer 110, and a subsidiary electrode 190 that is disposed on a front surface or a top surface of the front electrode 170 and the photovoltaic layer 110 and that may be substantially transparent.

The photovoltaic layer 110 may generate electricity when it receives light. The photovoltaic layer 110 may include at least one of various inorganic or organic semiconductors and polymers, for example, silicon (Si), germanium (Ge), Cu—In—Ga—Se (CIGS), CdTe, group III-V compound semiconductors including InGaP, InGaAs, GaAs, etc. However, example embodiments are not limited thereto. The photovoltaic layer 110 may have a single layer structure, a dual-layered structure, or a multiple-layered structure, and may be flexible.

The front electrodes 170 and the rear electrode 180 may include at least one layer of a metal or metals having low resistivity, for example, titanium (Ti), gold (Au), silver (Ag), and copper (Cu). The front electrodes 170 and the rear electrode 180 may have a thickness of about 300 nm to about 5 μm. Spaced apart front electrodes 170 may be connected to each other, for example, FIG. 2 shows a netlike shape of the front electrodes 170.

The subsidiary electrode 190 may include a transparent conductive material, for example, a transparent conductive oxide (TCO) such as indium tin oxide (ITO) or indium zinc oxide (IZO), or graphene. The graphene used for the subsidiary electrode 190 may include monolayer graphene or multilayer graphene having a conductive property. The graphene may be manufactured in various ways, for example, epitaxial growth on a catalysis layer, epitaxial growth on silicon carbide, and graphite exfoliation. The graphene may include one to ten atomic layers and the graphene may include a doped graphene sheet, but example embodiments are not limited thereto.

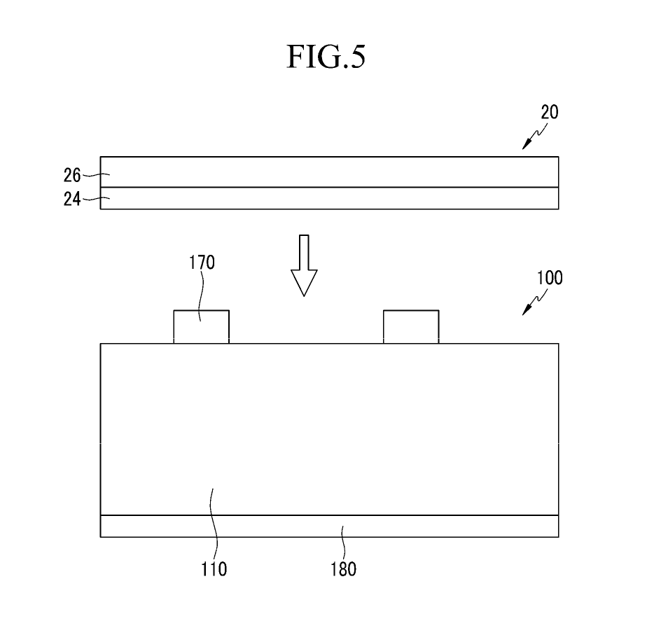

According to example embodiments, referring to FIG. 3, a graphene layer 24 may be grown on a catalysis layer 22 including a metal. Referring to FIG. 4, a transfer substrate 26 may be attached to the graphene layer 24. The transfer substrate 26 may include at least one of polydimethylsiloxane (PDMS), poly(methyl methacrylate) (PMMA), for example. Referring to FIG. 5, after the catalysis layer 22 may be removed away, the graphene layer 24 of a laminate 20 including the graphene layer 24 and the transfer substrate 26 may be adhered to surfaces of the front electrode 170 and the photovoltaic layer 110. Finally, the transfer substrate 26 may be removed to complete the formation of the solar cell 100 shown in FIG. 1. Here, the graphene layer 24 shown in FIG. 3 to FIG. 5 corresponds to the subsidiary electrode 190 shown FIG. 1.

The subsidiary electrode 190 may reduce the resistance, and may create various moving paths of charge carriers such as electrons, thereby improving the current flows to improve the efficiency of power generation. Furthermore, the width of the front electrode 170 may be reduced such that a light-receiving area is increased to improve the efficiency of power generation.

Graphene may be suitable for the subsidiary electrode 190. TCOs, for example ITO or IZO, may be relatively expensive and may be relatively fragile to be broken or cracked compared to graphene.

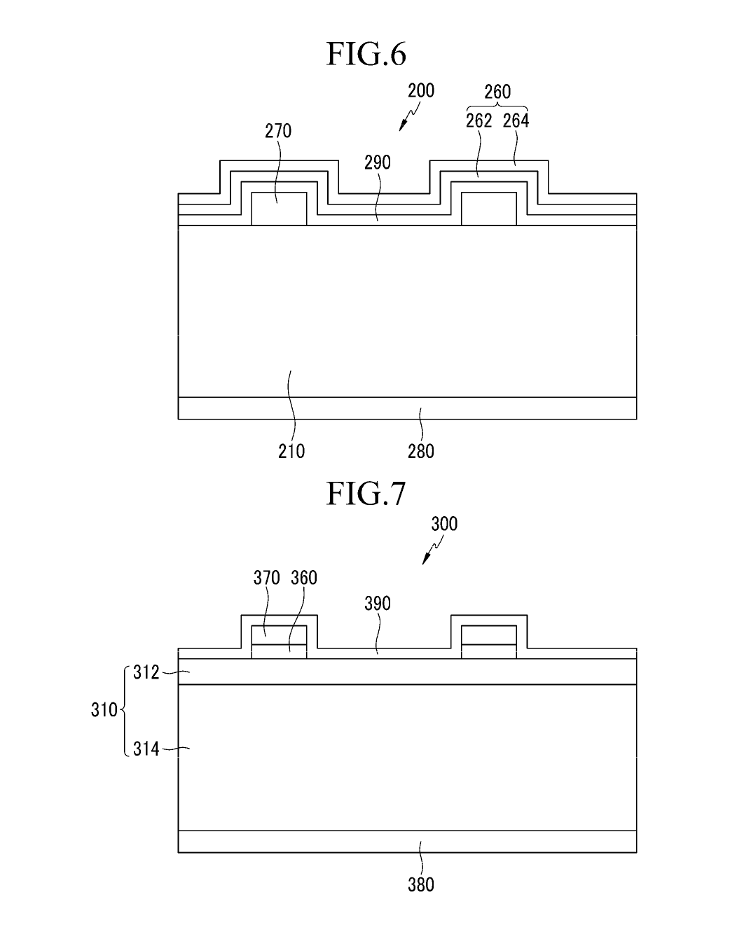

A solar cell according to example embodiments is described in detail with reference to FIG. 6.

FIG. 6 is a schematic sectional view of a solar cell according to example embodiments.

Referring to FIG. 6, a solar cell 200 according to example embodiments may include a photovoltaic layer 210, a plurality of front electrodes 270, a rear electrode 280, and a subsidiary electrode 290, like the solar cell 100 shown in FIG. 1.

However, the solar cell 200 according to example embodiments may further include an anti-reflection coating 260 disposed on the subsidiary electrode 290, unlike the solar cell 100 shown in FIG. 1.

The anti-reflection coating 260 may be provided to reduce (and/or prevent) reflection of incident light, and may include a material having a refractive index greater than air. The anti-reflection coating 260 may have a multi-layered structure, for example, a double-layered structure including a lower layer 262 and an upper layer 264. The refractive index of the lower layer 262 may be greater than the refractive index of the upper layer 264. For example, the lower layer 262 may include ZnS, and the upper layer 264 may include MgF₂. However, example embodiments are not limited thereto. The lower layer 262 may be omitted.

The graphene that may be used in the subsidiary electrode 290 may have a refractive index of about 2.4 to about 3.0, which is similar to a refractive index (about 2.5 to about 2.9) of ZnS. Therefore, the subsidiary electrode 290 of graphene may be substituted for the lower layer 262 of ZnS or the anti-reflection coating 260 as a whole, or may be compatible with the anti-reflection coating 260. However, a TCO that may have a refractive index lower than about 2.3 may not be substitute for the anti-reflection coating 260.

Other portions of the solar cell 200 may be the same (and/or substantially the same) as those of the solar cell 100 shown in FIG. 1, and the detailed description thereof is omitted.

A solar cell according to example embodiments is described in detail with reference to FIG. 7.

FIG. 7 is a schematic sectional view of a solar cell according to example embodiments.

Referring to FIG. 7, a solar cell 300 according to example embodiments may include a photovoltaic layer 310, a plurality of front electrodes 370, a rear electrode 380, and a subsidiary electrode 390, like the solar cell 100 shown in FIG. 1. The solar cell 300 according to example embodiments may further include a contact layer 360 disposed between the front electrodes 370 and the photovoltaic layer 310.

The photovoltaic layer 310 may have a single P-N junction structure including a first semiconductor film 312 and a second semiconductor film 314 that have reverse electrical conductivities. For example, the first semiconductor film 312 disposed close to the front electrodes 370 may be N-type, and the second semiconductor film 314 disposed close to the rear electrode 380 may be P-type. On the contrary, the first semiconductor film 312 may be P-type, and the second semiconductor film 314 may be N-type. The first and second semiconductor films 312 and 314 may include GaAs, for example.

The contact layer 360 may be provided to reduce contact resistance between the front electrodes 370 and the photovoltaic layer 310, and may include GaAs doped with at least one impurity, for example.

The solar cell 300 according to example embodiments may further include the anti-reflection coating 260 shown in FIG. 6. The anti-reflection coating 260 may cover the subsidiary electrode 390 and the front electrodes 370.

Other portions of the solar cell 300 may be substantially the same as those of the solar cell 100 shown in FIG. 1, and the detailed description thereof is omitted.

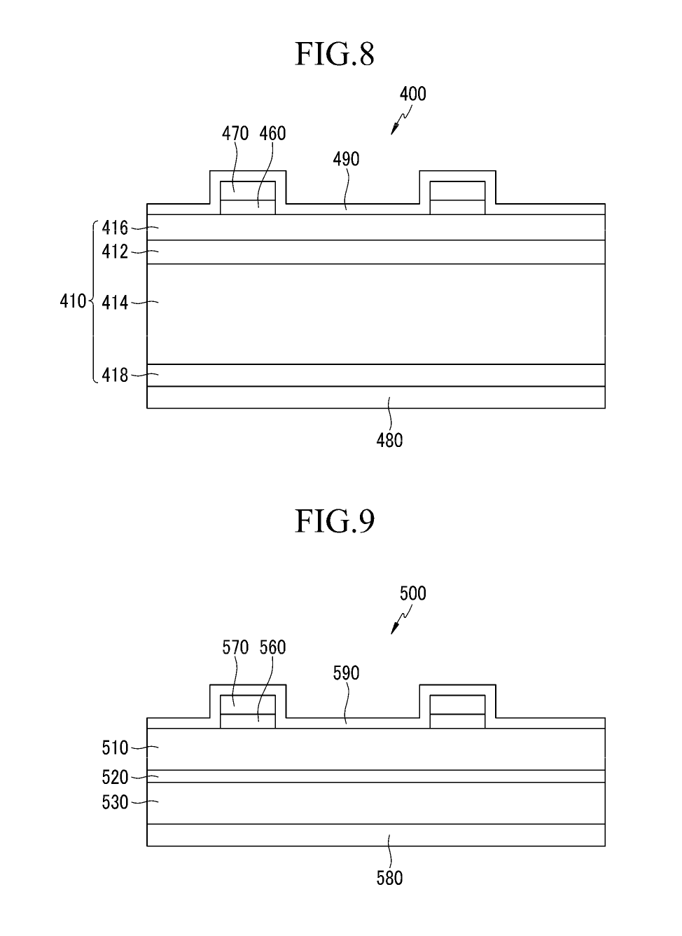

A solar cell according to example embodiments is described in detail with reference to FIG. 8.

FIG. 8 is a schematic sectional view of a solar cell according to example embodiments.

Referring to FIG. 8, a solar cell 400 according to example embodiments may include a photovoltaic layer 410, a contact layer 460, a plurality of front electrodes 470, a rear electrode 480, and a subsidiary electrode 490, and the photovoltaic layer 410 may include a first semiconductor film 412 and a second semiconductor film 414 forming a single P-N junction structure, like the solar cell 300 shown in FIG. 7.

The photovoltaic layer 410 may further include a window film 416 disposed between the first semiconductor film 412 and the contact layer 460, and a back surface field (BSF) film 418 disposed between the second semiconductor film 414 and the rear electrode 480.

The window film 416 may include a semiconductor having the same conductivity as the first semiconductor film 412, and may form a hetero-junction with the first semiconductor film 412. The BSF film 418 may include a semiconductor having the same conductivity as the second semiconductor film 414, and may form a hetero-junction with the second semiconductor film 414. According to example embodiments, the first and second semiconductor films 412 and 414 may include N-type and P-type (In)GaAs, respectively, and the window film 416 and the BSF film 418 may respectively include N-type and P-type AlInP or InGaP.

A junction of the window film 416 and the first semiconductor film 412 form a barrier that may reduce (and/or block) the movement of minority charge carriers in a reverse direction. Similarly, a junction of the BSF film 418 and the second semiconductor film 414 may form another barrier. In this way, minority charge carriers produced in the first and second semiconductor films 412 and 414 may move more smoothly in proper directions.

The window film 416 may have a resistance greater than a resistance of the subsidiary electrode 490.

According to example embodiments, one of the window film 416 and the BSF film 418 may be omitted.

The solar cell 400 according to example embodiments may further include the anti-reflection coating 260 shown in FIG. 6.

Other portions of the solar cell 400 may be substantially the same as those of the solar cell 100 shown in FIG. 1, and the detailed description thereof is omitted.

In this structure, the charge carriers may move in the low-resistive subsidiary electrode 490 rather than in the window film 416 horizontally, and then, may move to the contact layer 460 or the front electrodes 470. Therefore, the subsidiary electrode 490 may improve the current flow, thereby improving the efficiency of power generation.

A solar cell according to example embodiments is described in detail with reference to FIG. 9.

FIG. 9 is a schematic sectional view of a solar cell according to example embodiments.

Referring to FIG. 9, a solar cell 500 according to example embodiments may include a contact layer 560, a plurality of front electrodes 570, a rear electrode 580, and a subsidiary electrode 590, like the solar cell 300 shown in FIG. 7. The solar cell 500 may further include a pair of photovoltaic layers 510 and 530 and an intermediate layer 520 disposed between the photovoltaic layers 510 and 530.

The photovoltaic layers 510 and 530 may include an upper photovoltaic layer 510 and a lower photovoltaic layer 530 deposited in sequence from the top. Each of the photovoltaic layers 510 and 530 may have a structure substantially the same as one of the photovoltaic layers 110, 210, 310 and 410 shown in FIG. 1 and FIG. 6 to FIG. 8. The upper photovoltaic layer 510 and the lower photovoltaic layer 530 may have respective bandgaps different from each other. For example, the bandgap of the upper photovoltaic layer 510 may be greater than the bandgap of the lower photovoltaic layer 530 such that, among incident lights, light having relatively short wavelength is absorbed in the upper photovoltaic layer 510, while light having relatively long wavelength is absorbed in the lower photovoltaic layer 530.

The intermediate layer 520 may serve as recombination center where electrons in the upper photovoltaic layer 510 and the lower photovoltaic layer 530 may pass through the intermediate layer 520 to the other of the photovoltaic layers 510 and 530 due to tunnel effect. The intermediate layer 520 may include a single layer or may have a P-N junction structure.

According to example embodiments, the upper photovoltaic layer 510 and the lower photovoltaic layer 530 may include, for example, amorphous silicon and microcrystalline silicon, respectively.

The solar cell 500 according to example embodiments may further include the anti-reflection coating 260 shown in FIG. 6.

Other portions of the solar cell 500 may be substantially the same as those of the solar cell 300 shown in FIG. 7, and the detailed description thereof is omitted.

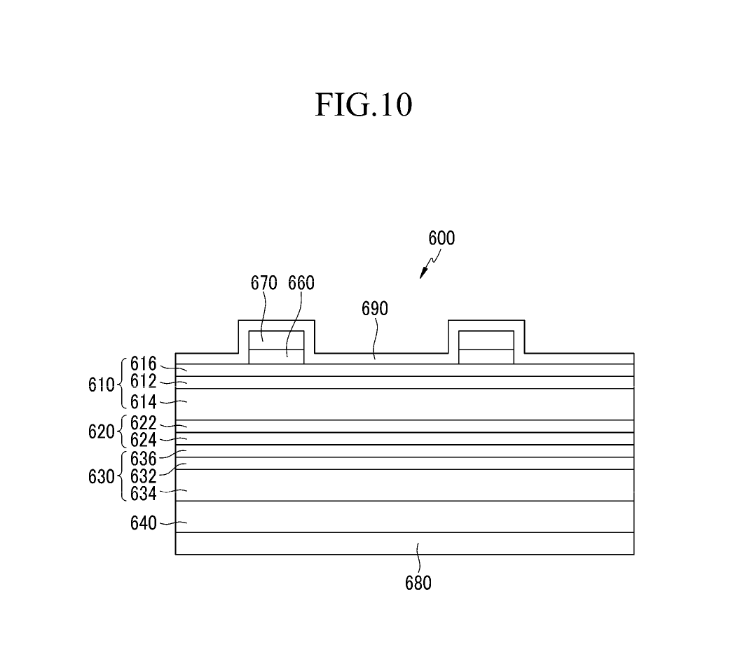

A solar cell according to example embodiments is described in detail with reference to FIG. 10.

FIG. 10 is a schematic sectional view of a solar cell according to example embodiments.

Referring to FIG. 10, a solar cell 500 according to example embodiments may include upper and lower photovoltaic layers 610 and 630, an intermediate layer or a tunnel-junction layer 620, a contact layer 660, a plurality of front electrodes 670, a rear electrode 680, and a subsidiary electrode 690, like the solar cell 500 shown in FIG. 9. The solar cell 600 may further include a substrate 640 disposed between the lower photovoltaic layers 630 and the rear electrode 680.

Each of the upper and lower photovoltaic layers 610 and 630 may include a window film 616 or 636, a first semiconductor film 612 or 632, and a second semiconductor film 614 or 634, which are deposited in sequence from the top. The first semiconductor films 612 and 632 of the upper and lower photovoltaic layers 610 and 630 may have the same conductivity, and the second semiconductor films 614 and 634 may also have the same conductivity. The conductivity of the second semiconductor films 614 and 634 may be different from the conductivity of the first semiconductor films 612 and 632. The window film 616 or 636 may include a semiconductor having the same conductivity as the first semiconductor film 612 or 632, and may form a hetero-junction with the first semiconductor film 612 or 632.

A bandgap of the upper photovoltaic layer 610 may be greater than a bandgap of the lower photovoltaic layer 630 such that, among incident lights, light having relatively short wavelength is absorbed in the upper photovoltaic layer 610, while light having relatively long wavelength is absorbed in the lower photovoltaic layer 630. At least one of the window films 616 and 636 may be omitted, and at least one of the photovoltaic layers 610 and 630 may include the BSF film 418 shown in FIG. 8.

The tunnel-junction layer 620 may include a semiconductor doped with impurity at a concentration greater than impurity concentrations of the upper and lower photovoltaic layers 610 and 630. The tunnel-junction layer 620 may include an upper film 622 and a lower film 624 deposited in sequence from the top. The upper film 622 may have the same conductivity as the second semiconductor film 614 of the upper photovoltaic layer 610, and the lower film 624 may have the same conductivity as the first semiconductor film 632 of the lower photovoltaic layer 630.

The substrate 640 may include a doped semiconductor having a conductivity that is the same as a conductivity of the second semiconductor film 634 of the lower photovoltaic layer 630.

According to example embodiments, the first and second semiconductor films 612 and 614 of the upper photovoltaic layer 610 may include GaInP, and the window film 616 of the upper photovoltaic layer 610 may include AlInP. The first and second semiconductor films 632 and 634 of the lower photovoltaic layer 630 may include GaAs, and the window film 636 of the lower photovoltaic layer 630 may include AlInP. The upper film 622 of the tunnel-junction layer 620 may include AlGaAs heavily doped with impurity, and the lower film 624 thereof may include GaAs heavily doped with impurity. The substrate 640 may include GaAs heavily doped with impurity.

The solar cell 600 according to example embodiments may further include the anti-reflection coating 260 shown in FIG. 6.

Other portions of the solar cell 600 may be substantially the same as those of the solar cell 500 shown in FIG. 9, and the detailed description thereof is omitted.

The substrate 640 shown in FIG. 10 may be applied to the solar cells 200 and 300 shown in FIG. 7 and FIG. 8.

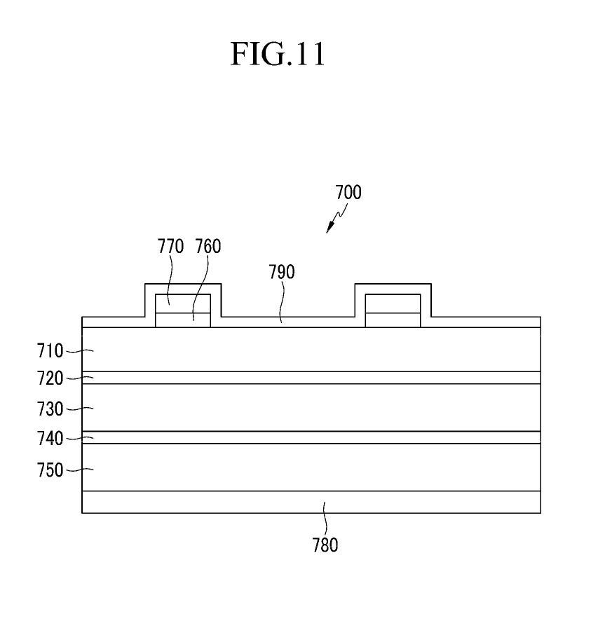

A solar cell according to example embodiments is described in detail with reference to FIG. 11.

FIG. 11 is a schematic sectional view of a solar cell according to example embodiments.

Referring to FIG. 11, a solar cell 700 according to example embodiments may include a contact layer 760, a plurality of front electrodes 770, a rear electrode 780, and a subsidiary electrode 790, like the solar cell 300 shown in FIG. 7. The solar cell 700 may further include a plurality of photovoltaic layers 710, 730 and 750 and a plurality of intermediate layer 720 and 740 disposed between the photovoltaic layers 710, 730 and 750.

The plurality of photovoltaic layers 710, 730 and 750 may include a lower photovoltaic layer 750, an intermediate photovoltaic layer 730, and an upper photovoltaic layer 710 deposited in sequence from the bottom. Each of the photovoltaic layers 710, 730 and 750 may have a structure substantially the same as one of the photovoltaic layers 110, 210, 310, 410, 510, 530, 610 and 630 shown in FIG. 1 and FIG. 6 to FIG. 10.

The photovoltaic layers 710, 730 and 750 may have respective bandgaps different from one another. For example, the bandgap may decrease from the upper photovoltaic layer 710 to the lower photovoltaic layer 730. According to example embodiments, the bandgap of the upper photovoltaic layer 710 may be greater than the bandgap of the intermediate photovoltaic layer 730, which in turn may be greater than the bandgap of the lower photovoltaic layer 750 such that, among incident lights, light having relatively short wavelength is absorbed in the upper photovoltaic layer 710, and light having intermediate wavelength is absorbed in the intermediate photovoltaic layer 730, while light having relatively long wavelength is absorbed in the lower photovoltaic layer 750.

The plurality of intermediate layers 720 and 740 may include an upper intermediate layer 720 disposed between the upper photovoltaic layer 710 and the intermediate photovoltaic layer 730, and a lower intermediate layer 740 disposed between the intermediate photovoltaic layer 730 and the lower photovoltaic layer 750. Each of the intermediate layers 720 and 740 may have a structure substantially the same as the intermediate layer 520 or 620 shown in FIG. 9 or FIG. 10.

According to example embodiments, the upper photovoltaic layer 710, the intermediate photovoltaic layer 730, and the lower photovoltaic layer 750 may include, for example, InGaP, InGaAs (or GaAs), and Germanium (Ge), respectively. Each of the intermediate layers 720 and 740 may have a double-layered structure, for example, including a AlGaAs film and a GaAs film deposited in sequence from the top.

The solar cell 700 according to example embodiments may further include the anti-reflection coating 260 shown in FIG. 6 and/or the substrate 640 shown in FIG. 10.

Other portions of the solar cell 700 may be substantially the same as those of the solar cell 300 shown in FIG. 7, and the detailed description thereof is omitted.

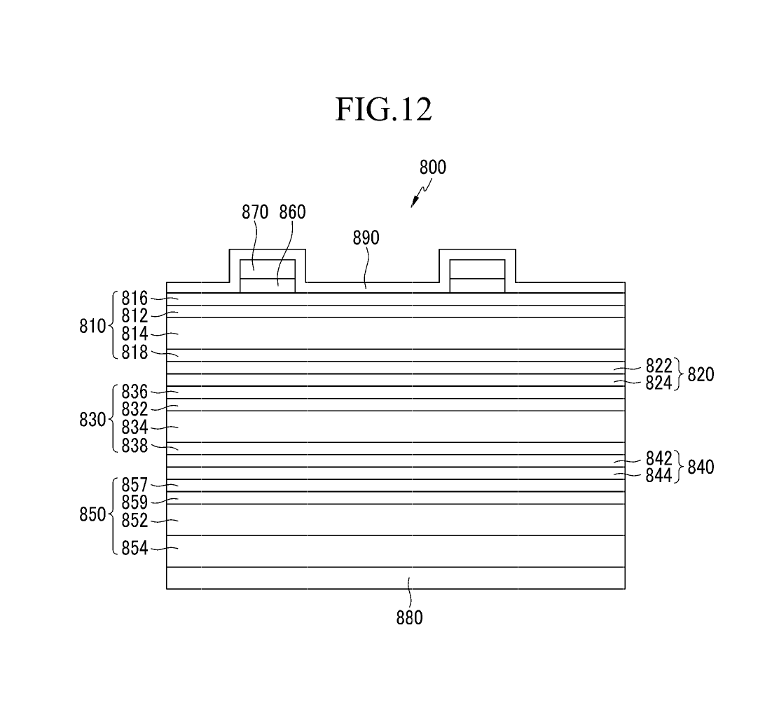

A solar cell according to example embodiments is described in detail with reference to FIG. 12.

FIG. 12 is a schematic sectional view of a solar cell according to example embodiments.

Referring to FIG. 12, a solar cell 800 according to example embodiments may include upper, intermediate, and lower photovoltaic layers 810, 830 and 850, upper and lower tunnel-junction layers 820 and 840, a contact layer 860, a plurality of front electrodes 870, a rear electrode 880, and a subsidiary electrode 890, like the solar cell 500 shown in FIG. 11.

Each of the upper and intermediate photovoltaic layers 810 and 830 may include a window film 816 or 836, a first semiconductor film 812 or 832, a second semiconductor film 814 or 834, and a BSF film 818 or 838, which are deposited in sequence from the top. The lower photovoltaic layer 850 may include a buffer film 857, a nucleation film 859, a first semiconductor film 852, and a second semiconductor film 854, which are deposited in sequence from the top.

The window films 816 and 836, the BSF films 818 and 838, the buffer film 857, and the nucleation film 859 may include semiconductors. The first semiconductor films 812 and 832 and the window films 816 and 836 of the upper and intermediate photovoltaic layers 810 and 830, and the first semiconductor film 852 and the buffer film 857 of the lower photovoltaic layer 850 may have the same conductivity. The second semiconductor films 814, 834 and 854 of the upper, intermediate, and lower photovoltaic layers 810, 830 and 850 may have the same conductivity as the BSF films 818 and 838 of the upper and intermediate photovoltaic layers 810 and 830. The first semiconductor films 812, 832 and 852, the window films 816 and 836, and the buffer film 857 may have a conductivity different from a conductivity of the second semiconductor films 814, 834 and 854 and the BSF films 818 and 838. The window films 816 and 836 and the BSF films 818 and 838 of the upper and intermediate photovoltaic layers 810 and 830 may have impurity concentrations greater than impurity concentrations of the first and second semiconductor films 812, 832, 852, 814, 834 and 854 of the upper, intermediate, and lower photovoltaic layers 810, 830 and 850, and the buffer film 857 of the lower photovoltaic layer 850. The window film 816 or 836 may form a hetero-junction with the first semiconductor film 812 or 832.

A bandgap of the upper photovoltaic layer 810 may be greater than a bandgap of the intermediate photovoltaic layer 830, which in turn may be greater than a bandgap of the lower photovoltaic layer 850 such that, among incident lights, light having relatively short wavelength is absorbed in the upper photovoltaic layer 810, and light having intermediate wavelength is absorbed in the intermediate photovoltaic layer 830, while light having relatively long wavelength is absorbed in the lower photovoltaic layer 850.

The plurality of tunnel-junction layers 820 and 840 may include a semiconductor doped with impurity at a concentration greater than impurity concentrations of the photovoltaic layers 810, 830 and 850. Each of the upper and lower tunnel-junction layers 820 and 840 may include an upper film 822 or 842 and a lower film 824 or 844 deposited in sequence from the top. The upper films 822 and 842 may have the same conductivity as the second semiconductor films 814 and 834, and the lower films 824 and 844 may have the same conductivity as the first semiconductor films 812 and 832.

According to example embodiments, the first and second semiconductor films 812 and 814 of the upper photovoltaic layer 810 may include InGaP, and the window film 816 and the BSF film 818 thereof may include AlInP and AlGaInP, respectively. The first and second semiconductor films 832 and 834 of the intermediate photovoltaic layer 830 may include InGaAs (or GaAs), and the window film 836 and the BSF film 838 thereof may include InGaP. The first and second semiconductor films 852 and 854 of the lower photovoltaic layer 850 may include Ge, and the buffer film 857 and the nucleation film 859 thereof may include InGaAs and InGaP, respectively. The upper films 822 and 842 of the tunnel-junction layers 820 and 849 may include AlGaAs, and the lower films 824 and 844 thereof may include GaAs.

The solar cell 800 according to example embodiments may further include the anti-reflection coating 260 shown in FIG. 6.

Other portions of the solar cell 800 may be substantially the same as those of the solar cell 700 shown in FIG. 11, and the detailed description thereof is omitted.

Although each of the above-described solar cells has one to three photovoltaic layers, the number of photovoltaic layers is not limited thereto. For example, the number of photovoltaic layers may be four or more.

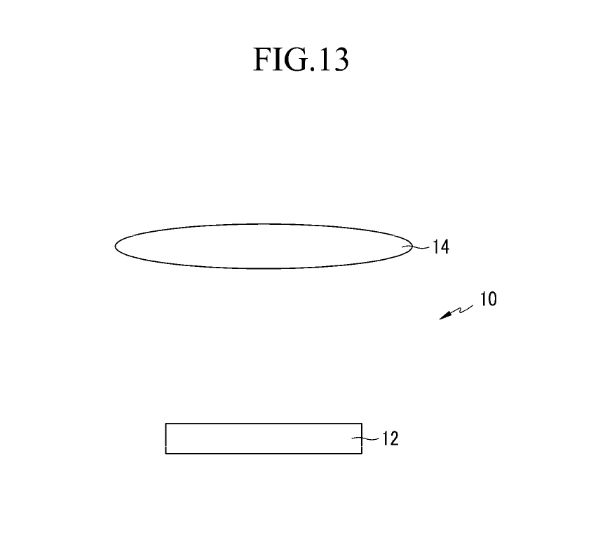

A solar cell according to example embodiments is described in detail with reference to FIG. 13.

FIG. 13 is a schematic sectional view of a solar cell according to example embodiments.

Referring to FIG. 13, a solar cell 10 according to example embodiments may include a photovoltaic member 12 and a concentrating member 14.

The photovoltaic member 12 may have one of the structures shown in FIG. 1 and FIG. 6 to FIG. 12. The concentrating member 14 may concentrate incident light and provide the concentrated light for the photovoltaic member 12. The concentrating member 14 may have a concentration ratio greater than one, for example, greater than about 180.

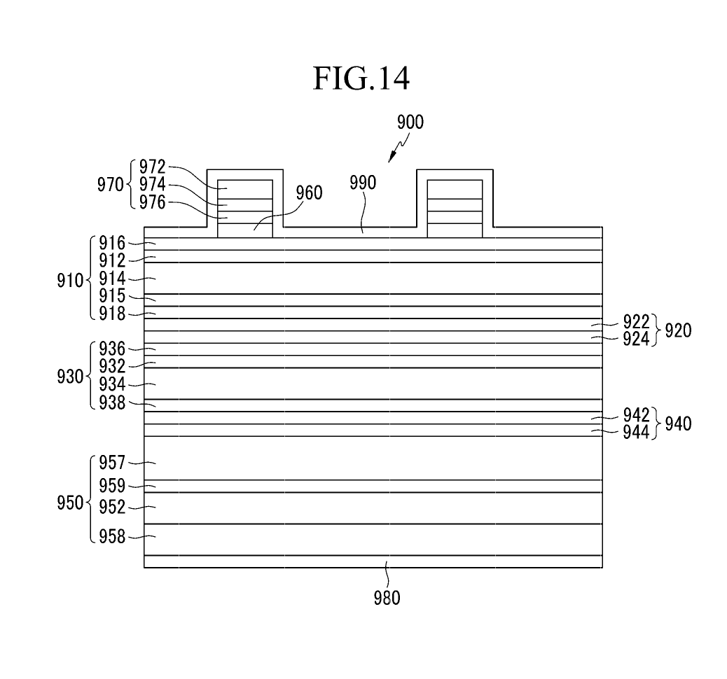

In this solar cell 10, the density of charge carriers may be higher to increase the effect of the subsidiary electrode 190, 290, 390, 490, 590, 690, 790 or 890 as the concentration ratio increases, which is described in detail with reference to FIG. 14 to FIG. 25.

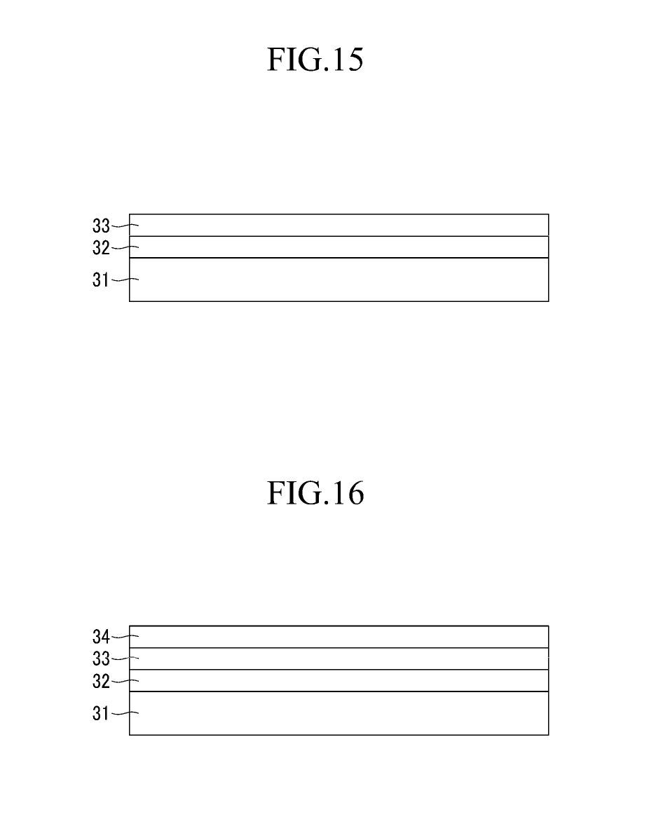

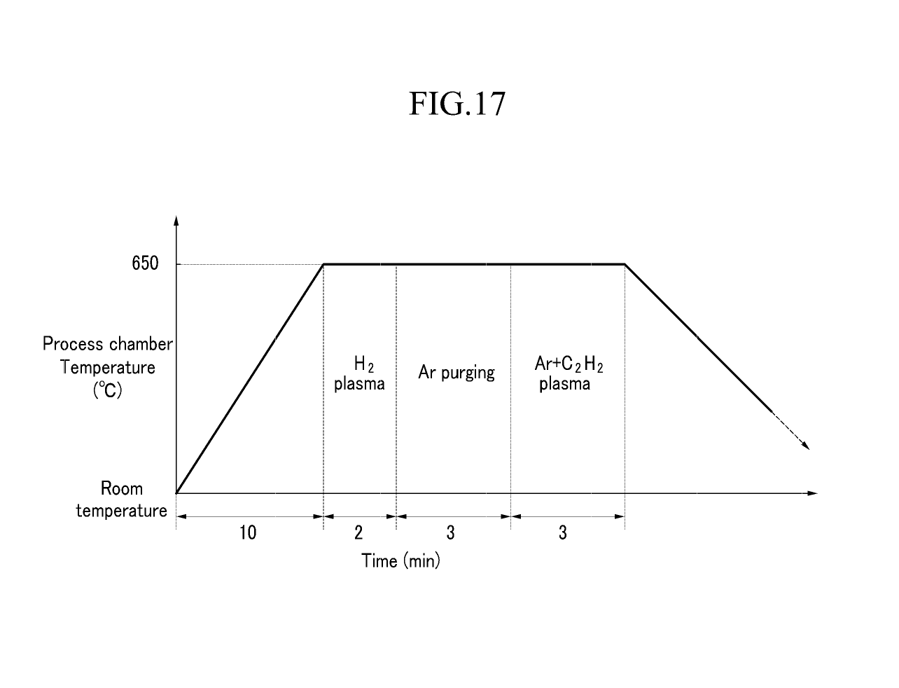

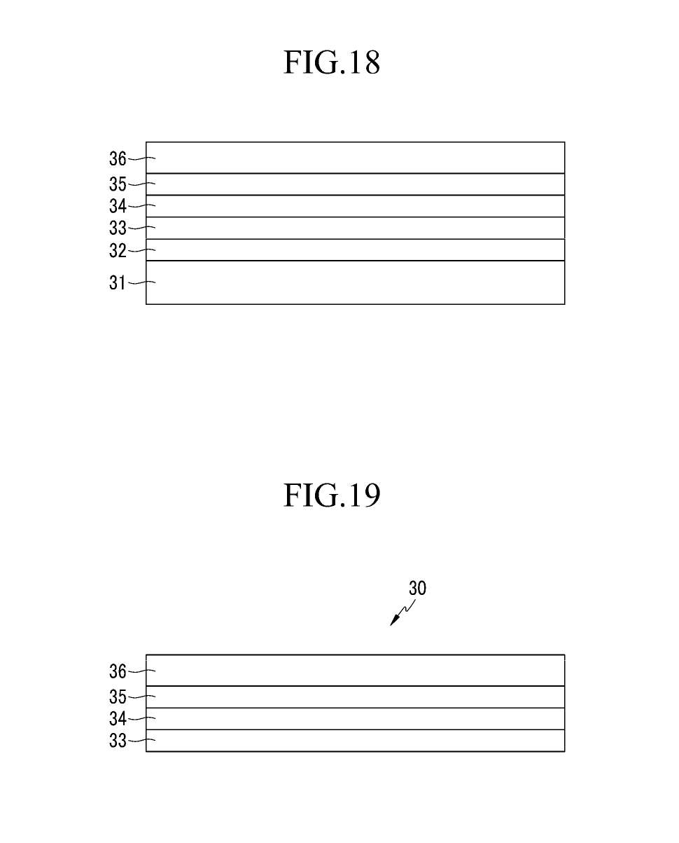

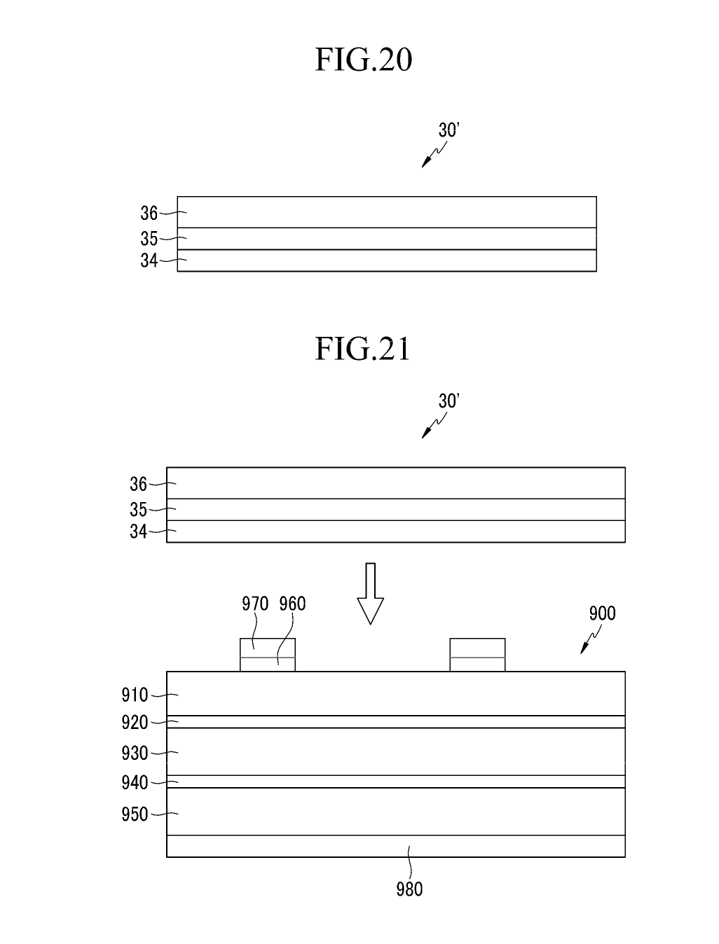

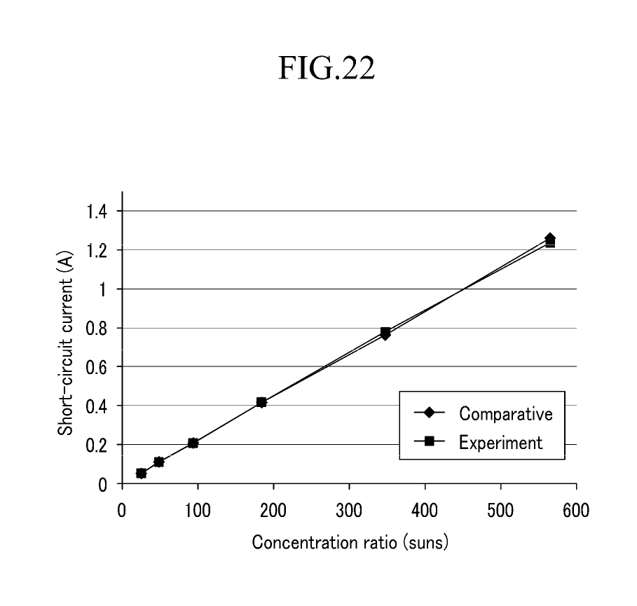

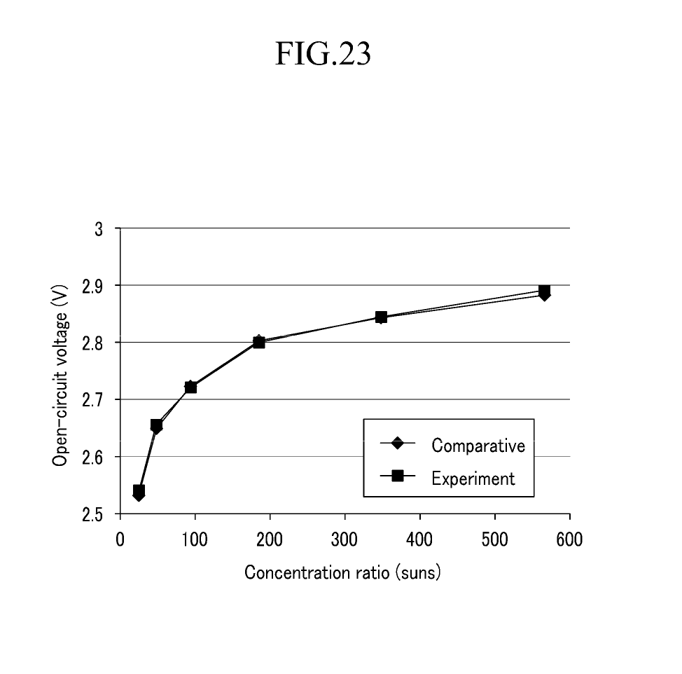

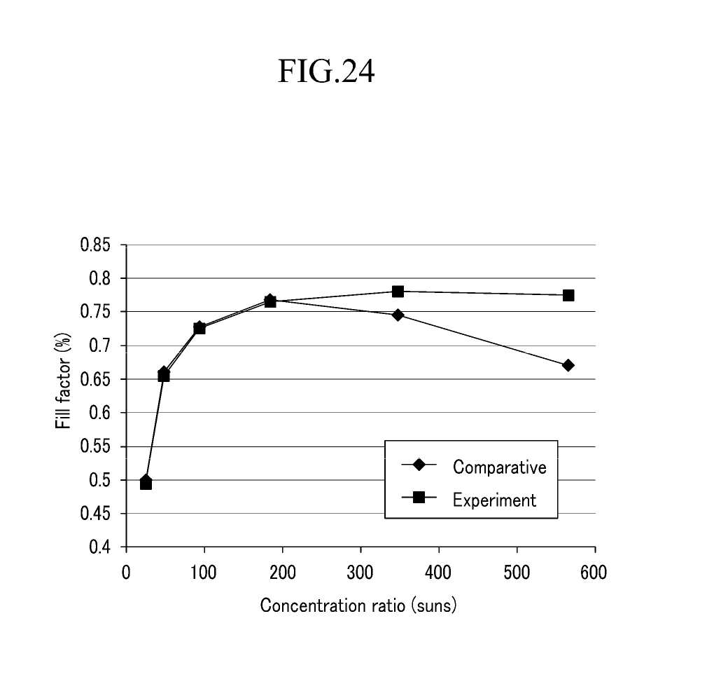

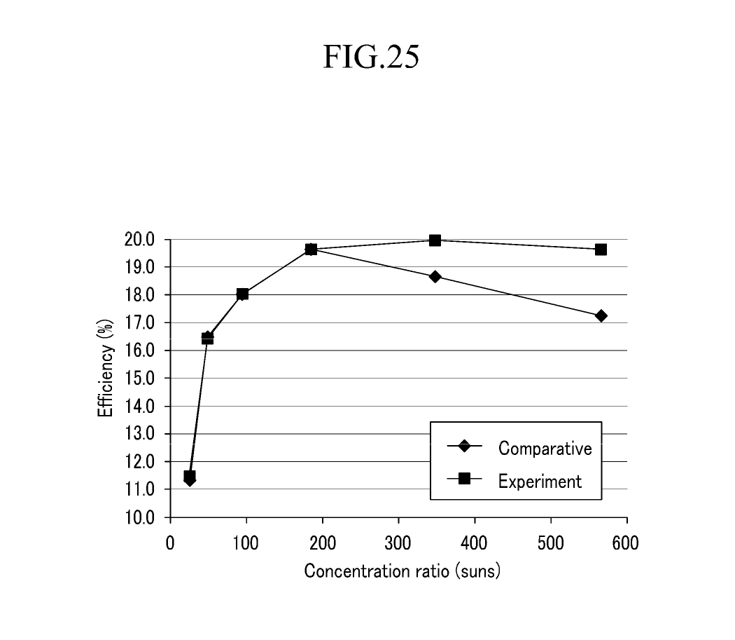

FIG. 14 is a schematic sectional view of a solar cell according to experiments. FIG. 15, FIG. 16, and FIG. 18 to FIG. 21 are schematic sectional views illustrating a method of forming a subsidiary electrode of a solar cell according to experiments. FIG. 17 is a graph showing a process condition for forming a subsidiary electrode of a solar cell according to experiments. FIG. 22 is a graph showing a short-circuit current of a solar cell according to an experiment and a comparative example as function of the concentration ratio. FIG. 23 is a graph showing an open-circuit voltage of a solar cell according to an experiment and a comparative example as function of the concentration ratio. FIG. 24 is a graph showing a fill factor of a solar cell according to an experiment and a comparative example as function of the concentration ratio. FIG. 25 is a graph showing an efficiency of a solar cell according to an experiment and a comparative example as function of the concentration ratio.

First, a solar cell according to an experiment, which has a structure shown in FIG. 14, and another solar cell according to an experiment, which has a structure shown in FIG. 14 without a subsidiary electrode 990, are manufactured.

Referring to FIG. 14, the experimental solar cell 900 includes upper, intermediate, and lower photovoltaic layers 910, 930 and 950, upper and lower tunnel-junction layers 920 and 940, a contact layer 960, front electrodes 970, a rear electrode 980, and a subsidiary electrode 990.

The upper photovoltaic layer 910 includes an N-type AlInP window 916, an N-type InGaP emitter 912, a P-type InGaP base 914, a high-concentration P-type InGaP BSF film 915, and a P-type AlInP BSF film 918, which are deposited in sequence from the top. The N-type films, including the window 916 and the emitter 912, are doped with silicon (Si). The P-type films, including the base 914, the InGaP BSF film 915, and the AlInP BSF film 918, are doped with zinc (Zn). The thicknesses of the films 916, 912, 914, 915 and 918 are about 0.03 μm, about 0.05 μm, about 0.55 μm, about 0.03 μm, and about 0.03 μm, respectively, from the top.

The intermediate photovoltaic layer 930 includes an N-type AlInP window 936, an N-type InGaAs emitter 932, a P-type InGaAs base 934, and a P-type InGaAs BSF film 938, which are deposited in sequence from the top. The N-type films, including the window 936 and the emitter 932, are doped with silicon Si. The P-type films, including the base 934 and the BSF film 938, are doped with zinc (Zn). The thicknesses of the films 936, 932, 934 and 938 about 0.02 μm, about 0.1 μm, about 3.0 μm, and about 0.1 μm, respectively, from the top.

The lower photovoltaic layer 950 includes an N-type InGaAs buffer film 957, an N-type InGaP nucleation film 959, an N-type Ge emitter 952, and a P-type Ge substrate 958, which are deposited in sequence from the top. The N-type buffer film 957 and the N-type nucleation film 959 are doped with silicon (Si), the N-type emitter 952 is doped with phosphorus (P). The thicknesses of the films 957, 959, 952, 958 are about 1 μm, about 0.015 μm, about 0.5 μm, and about 150 μm, respectively, from the top.

Each of the upper and lower tunnel-junction layers 920 and 940 includes a P-type AlGaAs film 922 or 942 and an N-type GaAs film 924 or 944, which are deposited in sequence from the top. The AlGaAs film 922 or 942 is doped with carbon (C), and the GaAs film 924 or 944 is doped with selenium (Se). The thickness of the AlGaAs film 922 or 942 is about 0.03 μm, and the thickness of GaAs film 924 or 944 is about 0.04 μm.

The contact layer 960 includes GaAs, and has a thickness of about 0.3 μm.

The front electrode 970 includes an upper film 972, an intermediate film 974, and a lower film 976, which are deposited in sequence from the top. The upper film 972, the intermediate film 974, and the lower film 976 includes silver (Ag), gold (Au), and titanium (Ti), respectively, and have thicknesses of about 5 μm, about 0.5 μm, and about 0.03 μm, respectively.

The photovoltaic layers 910, 930 and 950, the tunnel-junction layers 920 and 940, and the contact layer 960 are formed by metal-organic chemical vapor deposition (MOCVD), and the front electrodes 970 and the rear electrode 980 are formed by electron-beam evaporation.

The subsidiary electrode 990 includes graphene, and is manufactured by following processes.

Referring to FIG. 15 and FIG. 16, first, a silicon oxide (SiO₂) layer 32 and a nickel (Ni) layer 33 are deposited in sequence on a silicon (Si) substrate 31, and a graphene layer 34 is grown by inductively coupled plasma enhanced chemical vapor deposition (ICP-CVD).

Referring to FIG. 17, in order to grow the graphene layer 34, first, the substrate 31 with the silicon oxide layer 32 and the nickel layer 33 are heated for about 10 minutes in a process chamber running a process at about 650° C. and a pressure of about 10⁻⁷ torr, and processed in a process chamber running an H₂ plasma treating process for about 2 minutes. After Argon (Ar) gas is flowed into a chamber about 3 minutes to discharge gases remaining in the chamber, acetylene (C₂H₂) is added such that carbon in the acetylene is melted into nickel, and the graphene layer 34 is grown on the nickel layer 33 by gradually dropping the temperature.

Referring to FIG. 18, a PMMA layer 35 is spin-coated on the graphene layer 34, and a UV curable pressure sensitive tape 36 is attached on the PMMA layer 35.

Referring to FIG. 19, the pressure sensitive tape 36 is peeled off to separate a laminate 30 including the nickel layer 33, the graphene layer 34, the PMMA layer 35, and the pressure sensitive tape 36 from the substrate 31 and the silicon oxide layer 32. The separation is obtained due to relatively weak adhesion between the nickel layer 33 and the silicon oxide layer 32.

Referring to FIG. 20, the laminate 30 illustrated in FIG. 19 is dipped into FeCl₃ to etch out the nickel layer 33, and cleaned with water to entirely expose the graphene layer 34. As a result, a laminate 30′ without the nickel layer 33 is formed.

Referring to FIG. 21, the laminate 30′ is aligned such that the graphene layer 34 of the laminate 30 faces surfaces of the front electrodes 970 and the upper photovoltaic layer 910 of the solar cell 900 without the subsidiary electrode 990, and the laminate 30 is adhered to the solar cell 900.

Finally, the pressure sensitive tape 36 and the PMMA layer 35 are removed by acetone and IPA (isopropyl alcohol), respectively, to complete manufacturing of the solar cell 900. Here, the graphene layer 34 becomes the subsidiary electrode 990.

The solar cells manufactured as described above according to the experiment and a comparative example are exposed to light. Various characteristics, such as a short-circuit current, an open-circuit voltage, a fill factor, and an efficiency of the solar cells are measured and determined depending on the concentration ratio. It is noted that the variation of the concentration ratio is obtained by changing the intensity of the incident light instead of using a concentrating member.

Referring to FIG. 22, the solar cells according to the experiment and the comparative example have nearly similar short-circuit currents the short-circuit current of the experimental solar cell was expected to be less since the graphene subsidiary electrode 990 may decrease the transmittance of the incident light. It may be inferred that the graphene subsidiary electrode 990 may serve as an anti-reflection coating to compensate for the decreased transmittance of the incident light.

Referring to FIG. 23, the open-circuit voltages of the solar cells according to the experiment and the comparative example are also nearly similar to each other.

Referring to FIG. 24, the fill factors of the solar cells according to the experiment and the comparative example are nearly similar to each other when the concentration ratio is lower than about 180. However, when the concentration ratio is equal to or greater than about 180, the fill factor of the experimental solar cell increases more than that of the comparative solar cell as the concentration ratio becomes high. The graphene subsidiary electrode 990 may reduce sheet resistance for current transportation to increase the fill factor, which is a characteristic related to resistance.

Referring to FIG. 25, the efficiencies of the experimental solar cell and the comparative solar cell are similar to each other when the concentration ratio is lower than about 180. However, when the concentration ratio is equal to or greater than about 180, the efficiency of the experimental solar cell becomes greater than that of the comparative solar cell as the concentration ratio becomes high.

As described above, the graphene subsidiary electrode of the experimental solar cell may reduce the resistance against current transportation to increase the fill factor and the efficiency.

While some example embodiments have been particularly shown and described, it will be understood by one of ordinary skill in the art that variations in form and detail may be made therein without departing from the spirit and scope of the claims.

What is claimed is:

1. A solar cell comprising:
a rear electrode;
a photovoltaic layer on the rear electrode;
a plurality of front electrodes on a front surface of the photovoltaic layer; and
a transparent subsidiary electrode on the front surface of the photovoltaic layer and a front surface of the plurality of front electrodes.

2. The solar cell of claim 1, wherein the subsidiary electrode comprises graphene.

3. The solar cell of claim 2, further comprising:
a concentrating member configured to concentrate incident light and to provide the concentrated light to the photovoltaic layer.

4. The solar cell of claim 3, wherein a concentration ratio of the concentrating member is equal to or greater than about 180.

5. The solar cell of claim 2, wherein
the photovoltaic layer includes a first semiconductor film and a second semiconductor film that form a first junction, and
a conductivity type of the first semiconductor film is different than a conductivity type of the second semiconductor.

6. The solar cell of claim 5, wherein the photovoltaic layer further includes:
a window film between the first semiconductor film and at least one of the plurality of front electrodes, and
the window film and the first semiconductor film form a second junction.

7. The solar cell of claim 6, wherein the photovoltaic layer further includes:
a back surface field film between the second semiconductor film and the rear electrode, and
the back surface field film and the second semiconductor film form a third junction.

8. The solar cell of claim 6, further comprising:
a contact layer between the window film and the at least one of plurality of front electrodes,
wherein the contact layer is configured to reduce electrical resistance between the window film and the front electrodes.

9. The solar cell of claim 2, further comprising:
an anti-reflection coating on a front surface of the subsidiary electrode.

10. A solar cell comprising:
a rear electrode;
a plurality of photovoltaic layers on the rear electrode;
at least one intermediate layer between adjacent photovoltaic layers among the plurality of photovoltaic layers;
a plurality of front electrodes on a front surface of the plurality of the photovoltaic layers; and
a transparent subsidiary electrode on the front surface of the plurality of the photovoltaic layers and a front surface of the plurality of front electrodes.

11. The solar cell of claim 10, wherein the subsidiary electrode comprises graphene.

12. The solar cell of claim 11, further comprising:
a concentrating member configured to concentrate incident light and to provide the concentrated light to the plurality of the photovoltaic layers.

13. The solar cell of claim 12, wherein a concentration ratio of the concentrating member is equal to or greater than about 180.

14. The solar cell of claim 11, wherein at least one of the plurality of the photovoltaic layers includes:
a first semiconductor film and a second semiconductor film that form a first junction, and
a conductivity type of the first semiconductor film is different than a conductivity type of the second semiconductor film.

15. The solar cell of claim 14, wherein the at least one of the plurality of the photovoltaic layers further includes:
a window film between the first semiconductor film and at least one of the plurality of front electrodes, and
the window film and the first semiconductor film form a second junction.

16. The solar cell of claim 15, wherein the at least one of the plurality of the photovoltaic layers further includes:
a back surface field film between the second semiconductor film and the rear electrode, and
the back surface field film and the second semiconductor film form a third junction.

17. The solar cell of claim 16, further comprising:
a contact layer between the window film and the at least one of the plurality of front electrodes,
wherein the contact layer configured to reduce electrical resistance between the window film and the at least one of the plurality of front electrodes.

18. The solar cell of claim 17, wherein the at least one intermediate layer has a P-N junction structure.

19. The solar cell of claim 11, further comprising:
an anti-reflection coating on a front surface of the subsidiary electrode.

20. A solar cell comprising:
a laminate including a plurality of front electrodes and a photovoltaic layer on a rear electrode;
a subsidiary electrode on the plurality of front electrodes and the photovoltaic layer of the laminate, the subsidiary electrode is formed by a process including,
forming a graphene layer on a catalyst layer,
attaching a transfer substrate on the graphene layer,
adhering the graphene layer to the plurality of front electrodes and the photovoltaic layer of the laminate, and
removing the transfer substrate.
